(19) United States
(12) Patent Application Publication
(10) Pub. No.: US 2025/0260259 A1
(43) Pub. Date: Aug. 14, 2025

(54) UNINTERRUPTIBLE POWER SUPPLY DEVICE

(71) Applicant: TMEIC Corporation, Tokyo (JP)

(72) Inventor: Koki NAKAMURA, Chuo-ku (JP)

(73) Assignee: TMEIC Corporation, Tokyo (JP)

(21) Appl. No.: 18/857,659

(22) PCT Filed: Nov. 8, 2022
(86) PCT No.: PCT/JP2022/041558

§ 371 Date: Oct. 17, 2024

(51) Int. Cl. H02J 9/06; H02M 1/00; H02M 1/10; H02M 1/32; H02M 3/00; H02M 7/00

(52) U.S. Cl. CPC H02J 9/062; H02M 1/007; H02M 1/10; H02M 1/327; H02M 3/003; H02M 7/003

(57) ABSTRACT

First and second bases are arranged to face each other. An inverter is mounted on either of the first and second bases. A converter is mounted on the first base. A chopper is mounted on the second base. At least some of fins thermally connected to the converter via the first base are thermally connected to the chopper via the second base.

### TECHNICAL FIELD

The present disclosure relates to an uninterruptible power supply device.

### BACKGROUND ART

For a power conversion device provided in an uninterruptible power supply device, a configuration including a converter that converts AC power supplied from an AC power supply into DC power, and stops when the AC power supply fails, a chopper that regulates a voltage of DC power supplied from a power storage device while the AC power supply is in failure, and an inverter that converts the DC power output from the converter or the DC power output from the power storage device into AC power and supplies the power to a load has been widely employed.

In such a power conversion device, the converter and the inverter are active under normal conditions where the AC power is normally supplied from the AC power supply. When a power failure occurs, that is, the supply of the AC power from the AC power supply is interrupted, the chopper and the inverter become active to continue power supply.

Then, a configuration where a converter, an inverter, and a chopper are mounted on one surface of one heat sink, fins are provided on the other surface of the heat sink, and air from a cooling fan is applied to the fins to release heat of the converter, the inverter, and the chopper is known. In such a configuration, some fins are not used to release heat in both a case where power supply is performed under normal conditions and a case where power supply is performed under a power failure, which results in a cooling structure that is low in fin utilization rate.

For example, a heat sink that increases the fin utilization rate is disclosed in Japanese Patent Laying-Open No. 2012-182159 (PTL 1). The heat sink disclosed in PTL 1 is provided with a heat pipe. This allows heat to diffuse throughout the fins, and thus allows the heat sink to efficiently release heat.

### CITATION LIST

### Patent Literature

PTL 1: Japanese Patent Laying-Open No. 2012-182159

### SUMMARY OF INVENTION

### Technical Problem

The use of the heat sink provided with the heat pipe as described above or a heat sink using a thermal diffusion material allows heat to diffuse throughout the fins. The use of the heat pipe or the thermal diffusion material, however, increases the cost of the device.

The present disclosure has been made to solve the above-described problems, and it is therefore an object of the present disclosure to provide an uninterruptible power supply device that allows not only a reduction in cost and size of the device, but also an increase in cooling efficiency.

### Solution to Problem

An uninterruptible power supply device of the present disclosure is connected between an AC power supply and a load. The uninterruptible power supply device includes a heat sink and a power conversion device. The heat sink includes first and second bases, and fins. The first and second bases are arranged to face each other. The fins are arranged between the first and second bases and coupled to both the first and second bases. The power conversion device is mounted on a surface of each of the first and second bases opposite to a surface to which the fins are coupled. The power conversion device includes a converter, a chopper, and an inverter. The converter converts AC power supplied from the AC power supply into DC power, and stops when the AC power supply fails. The chopper regulates a voltage of DC power supplied from a power storage device while the AC power supply is in failure. The inverter converts the DC power output from the converter or the DC power output from the power storage device into AC power to supply power to the load. The inverter is mounted on either of the first and second bases. The converter is mounted on the first base. The chopper is mounted on the second base. At least some of the fins thermally connected to the converter via the first base are thermally connected to the chopper via the second base.

### Advantageous Effects of Invention

According to the present disclosure, it is possible to provide the uninterruptible power supply device that allows not only a reduction in cost and size of the device, but also an increase in cooling efficiency.

### BRIEF DESCRIPTION OF DRAWINGS

FIG. 1 is a diagram for describing a circuit configuration of an uninterruptible power supply device.

FIG. 2 is a diagram for describing the circuit configuration of the uninterruptible power supply device.

FIG. 3 is a plan view of a heat sink and a power conversion device in the related art.

FIG. 4 is a front view of the heat sink and the power conversion device illustrated in FIG. 3.

FIG. 5 is a front view of the heat sink and the power conversion device illustrated in FIG. 3.

FIG. 6 is a plan view of a heat sink and a power conversion device according to the present embodiment.

FIG. 7 is a bottom view of the heat sink and the power conversion device illustrated in FIG. 6.

FIG. 8 is a front view of the heat sink and the power conversion device illustrated in FIG. 6.

FIG. 9 is a front view of the heat sink and the power conversion device illustrated in FIG. 6.

FIG. 10 is a front view of a heat sink and a power conversion device according to a first modification.

FIG. 11 is a front view of a heat sink and a power conversion device according to a second modification.

### DESCRIPTION OF EMBODIMENTS

Hereinafter, an embodiment of the present disclosure will be described in detail with reference to the drawings. Note that, in the following description, the same or corresponding parts in the drawings are denoted by the same reference numerals, and no redundant description will be given of such parts in principle.

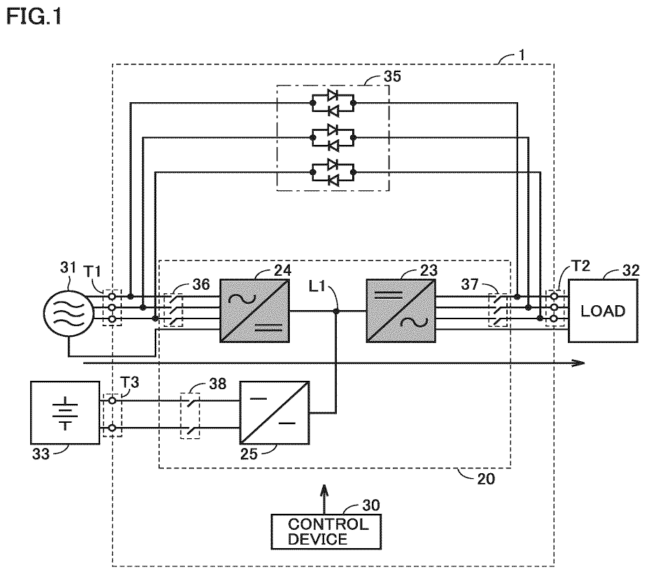

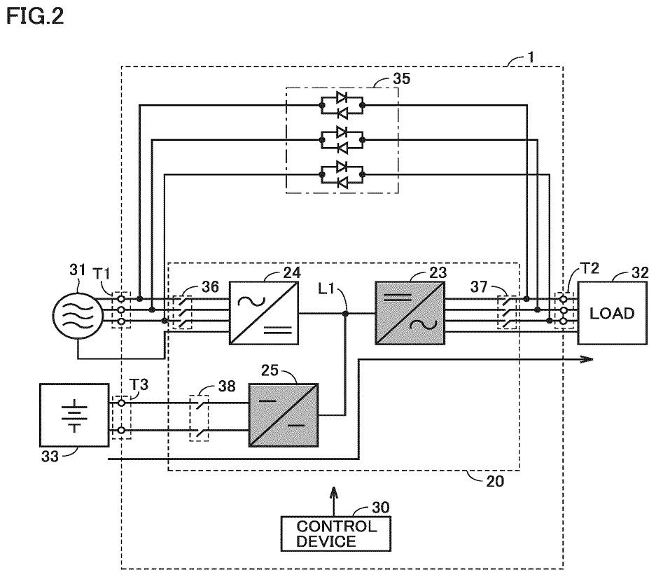

FIGS. 1 and 2 are diagrams for describing a circuit configuration of an uninterruptible power supply device 1. Uninterruptible power supply device 1 is connected between a commercial AC power supply 31 and a load 32. Uninterruptible power supply device 1 first converts three-phase AC power from commercial AC power supply 31 into DC power, then converts the DC power into three-phase AC power, and finally supplies the three-phase AC power to load 32.

Uninterruptible power supply device 1 includes a power conversion device 20, a bypass circuit (semiconductor switch) 35, and a control device 30. Power conversion device 20 includes a converter 24, a chopper 25, and an inverter 23.

Converter 24 converts AC power supplied from commercial AC power supply 31 into DC power. Converter 24 stops when commercial AC power supply 31 fails. Chopper 25 regulates a voltage of DC power supplied from a power storage device (hereinafter, also referred to as “battery”) 33 while commercial AC power supply 31 is in failure. Inverter 23 converts DC power output from converter 24 or DC power output from battery 33 into AC power and supplies the AC power to load 32.

Converter 24, chopper 25, and inverter 23 each include an insulated gate bipolar transistor (IGBT) and a diode. The IGBT acts as a “switching element”.

In the present embodiment, uninterruptible power supply device 1 performs inverter power supply, battery power supply, or bypass power supply. During the inverter power supply, converter 24 converts AC power supplied from commercial AC power supply 31 into DC power, and inverter 23 converts the DC power into AC power and supplies the AC power to load 32.

During the bypass power supply, AC power supplied from commercial AC power supply 31 is supplied to load 32 via semiconductor switch 35, that is, without passing through either converter 24 or inverter 23. During the battery power supply, chopper 25 regulates the voltage of DC power supplied from battery 33, and inverter 23 converts the DC power into AC power and supplies the AC power to load 32.

Uninterruptible power supply device 1 further includes an AC input terminal T1, an AC output terminal T2, a battery terminal T3, and electromagnetic contactors 36 to 38. AC input terminal T1 receives AC power of a commercial frequency from commercial AC power supply 31. AC output terminal T2 is connected to load 32. Load 32 is driven by AC power. Battery terminal T3 is connected to battery 33. Battery 33 stores DC power.

Electromagnetic contactor 36 is connected between AC input terminal T1 and an input node of converter 24. Electromagnetic contactor 36 is on while uninterruptible power supply device 1 is in use, and is off, for example, while uninterruptible power supply device 1 is under maintenance.

Under normal conditions where AC power is supplied from commercial AC power supply 31 (during the inverter power supply), converter 24 is controlled by control device 30 to convert (rectify) three-phase AC power into DC power and outputs the DC power to a DC line L1. When a power failure occurs, that is, the supply of AC power from commercial AC power supply 31 is interrupted, converter 24 is brought to a stop. It is possible to regulate the output voltage of converter 24 to a desired value.

DC line L1 is connected to a high-voltage side node of chopper (bidirectional chopper) 25, and a low-voltage side node of chopper 25 is connected to battery terminal T3 via electromagnetic contactor 38. Electromagnetic contactor 38 is on while uninterruptible power supply device 1 is in use, and is off, for example, while uninterruptible power supply device 1 and battery 33 are under maintenance.

Chopper 25 is controlled by control device 30 to store DC power generated by converter 24 into battery 33 under normal conditions where AC power is supplied from commercial AC power supply 31 (during the inverter power supply) and to supply DC power of battery 33 to inverter 23 through DC line L1 when an instantaneous voltage drop or a power failure occurs (during the battery power supply).

In a case where DC power is stored into battery 33, chopper 25 steps down a DC voltage of DC line L1 and feeds the stepped-down DC voltage to battery 33. Further, in a case where the DC power of battery 33 is supplied to inverter 23, chopper 25 boosts the voltage across the terminals of battery 33 and outputs the voltage to DC line L1. DC line L1 is connected to an input node of inverter 23.

Inverter 23 is controlled by control device 30 to convert (invert) DC power supplied from converter 24 or chopper 25 through DC line L1 into three-phase AC power of a commercial frequency and outputs the three-phase AC power. That is, inverter 23 converts the DC power supplied from converter 24 through DC line L1 into three-phase AC power under normal conditions (during the inverter power supply), and converts the DC power supplied from battery 33 via chopper 25 into three-phase AC power when an instantaneous voltage drop or a power failure occurs, that is, during the battery power supply. It is possible to regulate the output voltage of inverter 23 to a desired value.

Inverter 23 is connected to AC output terminal T2 via electromagnetic contactor 37. Electromagnetic contactor 37 is controlled by control device 30, and is on during the inverter power supply or the battery power supply, and is off during the bypass power supply.

Semiconductor switch 35 includes a thyristor switch having a pair of thyristors connected in antiparallel, and is connected between AC input terminal T1 and AC output terminal T2. Semiconductor switch 35 is controlled by control device 30, and is off during the inverter power supply or the battery power supply, and is on during the bypass power supply. For example, when inverter 23 suffers a breakdown during the inverter power supply, semiconductor switch 35 is quickly turned on to supply three-phase AC power from commercial AC power supply 31 to load 32.

Control device 30 controls entire uninterruptible power supply device 1. Control device 30 can be implemented by, for example, a microcomputer or the like. As an example, control device 30 includes a memory and a central processing unit (CPU) (not illustrated), and can perform a control operation by software processing performed in accordance with a program prestored in the memory and executed by the CPU. Alternatively, part or all of the control operation can be implemented by hardware processing using a built-in dedicated electronic circuit or the like, rather than the software processing.

AC input terminal T1 receives a three-phase AC voltage (U-phase AC voltage, V-phase AC voltage, and W-phase AC voltage) from commercial AC power supply 31. A three-phase AC voltage synchronized with the three-phase AC voltage from commercial AC power supply 31 is output to AC output terminal T2. Load 32 is driven by the three-phase AC voltage from AC output terminal T2.

As illustrated in FIG. 1, since converter 24 and inverter 23 are active during the inverter power supply, the amount of heat released from converter 24 and inverter 23 becomes large. Further, chopper 25 is also active to charge battery 33, but the amount of heat released from chopper 25 is considerably smaller than the amount of heat released from converter 24.

As illustrated in FIG. 2, since chopper 25 and inverter 23 are active during the battery power supply, the amount of heat released from chopper 25 and inverter 23 becomes large. In this case, since power is not supplied from commercial AC power supply 31, converter 24 is inactive.

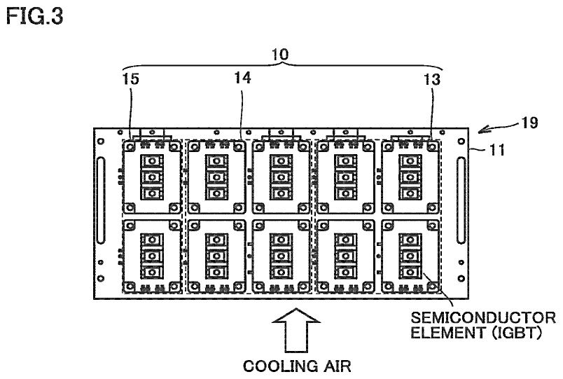

In the present embodiment, power conversion device 20 is mounted on a heat sink. With reference to FIGS. 3 to 5, a heat sink 19 and a power conversion device 10 in the related art will be described first. FIG. 3 is a plan view of heat sink 19 and power conversion device 10 in the related art.

As illustrated in FIG. 3, heat sink 19 includes a base 11. Power conversion device 10 includes an inverter 13, a converter 14, and a chopper 15.

Inverter 13, converter 14, and chopper 15 of power conversion device 10 each include a plurality of semiconductor elements (IGBT). In this example, inverter 13 includes four semiconductor elements, converter 14 includes four semiconductor elements, and chopper 15 includes two semiconductor elements, but this is merely an example, and inverter 13, converter 14, and chopper 15 may each include any number of semiconductor elements.

Inverter 13, converter 14, and chopper 15 of power conversion device 10 are mounted on base 11. Note that power conversion device 10 also has the same circuit configuration as illustrated in FIG. 1, and commercial AC power supply 31, load 32, and battery 33 are connected to power conversion device 10.

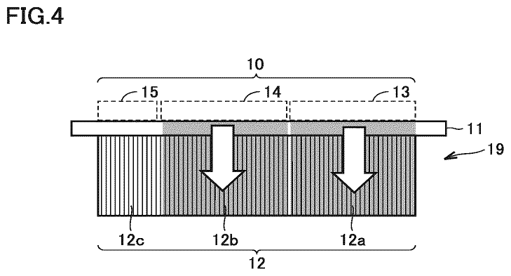

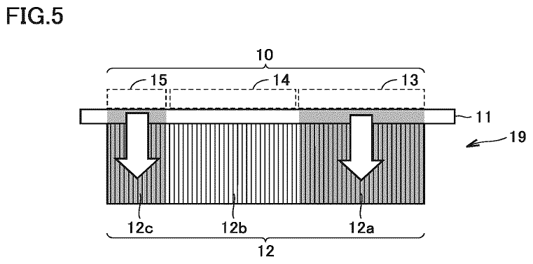

FIGS. 4 and 5 are front views of heat sink 19 and power conversion device 10 illustrated in FIG. 3. As illustrated in FIG. 4, heat sink 19 further includes fins 12. Fins 12 are coupled to a surface of base 11 of heat sink 19 opposite to a surface on which power conversion device 10 (inverter 13, converter 14, chopper 15) is mounted.

Fins 12 include fins 12a to 12c. Fins 12a are thermally connected to inverter 13 via base 11. Fins 12b are thermally connected to converter 14 via base 11. Fins 12c are thermally connected to chopper 15 via base 11. That is, the heat of inverter 13 is released from fins 12a, the heat of converter 14 is released from fins 12b, and the heat of chopper 15 is released from fins 12c.

Heat sink 19 has comb-shaped gaps provided by fins 12 so as to allow its front side to receive cooling air (see FIG. 3) from a cooling fan (not illustrated) and let the cooling air out toward the other side. Heat sink 19 causes base 11 to receive the heat of the semiconductor elements and transfer the heat to fins 12 by means of heat conduction of the individual. A mechanism for transporting heat from the surfaces of fins 12 to air by means of heat transfer is provided. Air from the cooling fan is applied to fins 12 to release the heat of the semiconductor elements.

As illustrated in FIG. 4, in a case where power is supplied from commercial AC power supply 31 (during the inverter power supply), since inverter 13 and converter 14 are active, the amount of heat released from fins 12a and 12b becomes large.

On the other hand, as illustrated in FIG. 5, in a case where power is supplied from battery 33 (during the battery power supply), since inverter 13 and chopper 15 are active, the amount of heat released from fins 12a and 12c becomes large.

As described above, during the inverter power supply (FIG. 4), fins 12a and 12b are effectively used to release heat, but fins 12c are not effectively used. On the other hand, during the battery power supply (FIG. 5), fins 12a and 12c are effectively used to release heat, but fins 12b are not effectively used.

In heat sink 19 and power conversion device 10 in the related art, inverter 13, converter 14, and chopper 15 are mounted on one base 11 in a row. It can be said that, in this device, some fins are not used to release heat during both the inverter power supply and the battery power supply, which makes the fin utilization rate low.

On the other hand, in the present embodiment, two bases on which inverter 23, converter 24, and chopper 25 are mounted are provided. Then, converter 24 is mounted on one base, and chopper 25 is mounted on the other base so as to face converter 24.

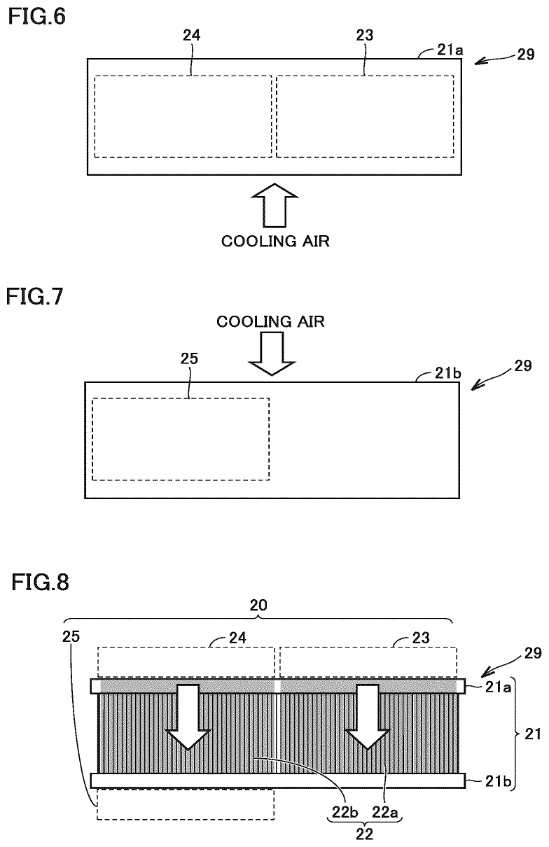

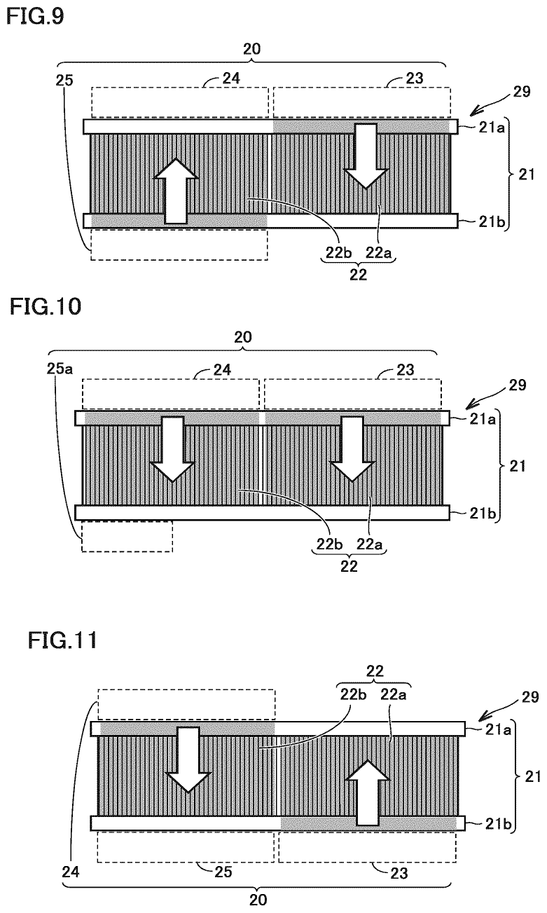

With reference to FIGS. 6 to 9, a heat sink 29 and power conversion device 20 according to the present embodiment will be described below. FIG. 6 is a plan view of heat sink 29 and power conversion device 20 according to the present embodiment. FIG. 7 is a bottom view of heat sink 29 and power conversion device 20 illustrated in FIG. 6. FIGS. 8 and 9 are front views of heat sink 29 and power conversion device 20 illustrated in FIG. 6.

Heat sink 29 includes a base 21 (base 21a and base 21b) and fins 22. Inverter 23, converter 24, and chopper 25 are mounted on base 21 (base 21a and base 21b).

As illustrated in FIG. 6 (plan view), converter 24 is mounted on base 21a. As illustrated in FIG. 7 (bottom view), chopper 25 is mounted on base 21b. Inverter 23 may be mounted on either base 21a or base 21b. In the present embodiment, inverter 23 is mounted on base 21a.

As in FIG. 3, inverter 23, converter 24, and chopper 25 each include a plurality of semiconductor elements (IGBT). Further, cooling is made by cooling air sent from a cooling fan in directions illustrated in FIGS. 6 and 7 in the same manner as in FIG. 3.

As illustrated in FIG. 8 (front view), base 21a and base 21b are arranged to face each other. Fins 22 are arranged between base 21a and base 21b, and are coupled to both base 21a and base 21b. Power conversion device 20 (inverter 23, converter 24, and chopper 25) is mounted on a surface of each of bases 21a and 21b opposite to a surface to which fins 22 are coupled.

In the present embodiment, at least some of fins 22 thermally connected to converter 24 via base 21a are thermally connected to chopper 25 via base 21b.

That is, at least some of fins 22 serve to release heat from both converter 24 and chopper 25 (there are fins used in common to release heat).

In the present embodiment, fins 22 includes fins 22a and fins 22b. Fins 22b are thermally connected to converter 24 via base 21a and are thermally connected to chopper 25 via base 21b. Fins 22a are thermally connected to inverter 23 via base 21 (base 21a or base 21b) on which inverter 23 is mounted.

In this example, converter 24 is identical in size (mounting area on the base) to chopper 25, so that the fins that release heat from converter 24 and the fins that release heat from chopper 25 coincide with each other.

During the inverter power supply, as illustrated in FIG. 8, since inverter 23 is active, the amount of heat released from fins 22a becomes large, and since converter 24 is active, the amount of heat released from fins 22b becomes large. In this case, the heat released from chopper 25 is considerably small, so that fins 22b are mainly used to release the heat from converter 24.

On the other hand, a case during the battery power supply is as illustrated in FIG. 9. Since inverter 23 is active, the amount of heat released from fins 22a becomes large, and since chopper 25 is active, the amount of heat released from fins 22b becomes large. In this case, converter 24 is not used, so that fins 22b are used to release the heat from chopper 25.

As described above, in uninterruptible power supply device 1 of the embodiment of the present invention, base 21a and base 21b are arranged to face each other. Fins 22 are arranged between base 21a and base 21b, and are coupled to both base 21a and base 21b. Power conversion device 20 is mounted on a surface of each of bases 21a and 21b opposite to a surface to which fins 22 are coupled. Inverter 23 is mounted on either base 21a or base 21b. Converter 24 is mounted on base 21a. Chopper 25 is mounted on base 21b. At least some of fins 22 thermally connected to converter 24 via base 21a are thermally connected to chopper 25 via base 21b.

Since either of converter 24 and chopper 25 is selectively used between the inverter power supply and the battery power supply, it is possible to increase both the fin utilization rate and the efficiency of cooling the device by using the fins in common between converter 24 and chopper 25. As a result, as compared with a case where a heat pipe or a thermal diffusion material is used to cause heat to diffuse throughout the fins (to increase the fin utilization rate), it is possible to reduce the cost of the device by making cooling only by air cooling. Further, two bases are provided on both sides of the fins, and inverter 23, converter 24, and chopper 25 are mounted on the two bases (elements are mounted on both the sides of the fins), so that the device can be downsized as compared with a device in which such components are mounted on one base. It is therefore possible to increase the cooling efficiency while reducing the cost and size of the device.

Further, fins 22 includes fins 22a and fins 22b. Fins 22b are thermally connected to converter 24 via base 21a and are thermally connected to chopper 25 via base 21b. Fins 22a are thermally connected to inverter 23 via base 21 (base 21a or base 21b) on which inverter 23 is mounted. As described above, since the fins (fins 22a) used by converter 24 and chopper 25 are different from the fins (fins 22b) used by inverter 23, the heat of converter 24 or chopper 25 causes no reduction in the efficiency of cooling inverter 23.

FIG. 10 is a front view of heat sink 29 and power conversion device 20 according to a first modification. In the first modification, a chopper 25a smaller in size (mounting area on the base) than converter 24 is mounted on base 21b. The other conditions are the same as those in the example described with reference to FIGS. 6 to 9.

Also in this case, it is only required that chopper 25a be mounted such that at least some of fins 22 thermally connected to converter 24 via base 21a are thermally connected to chopper 25a via base 21b. In the first modification, of fins 22b, fins used by chopper 25a are also used by converter 24.

Further, in a case where chopper 25a is larger in size than converter 24, the size (mountable area) of bases 21a and 21b may be increased so as to avoid the fins used by chopper 25a and the fins used by inverter 23 from overlapping each other. Alternatively, if space saving is important, the fins used by chopper 25a and the fins used by inverter 23 may overlap each other. In the latter case, mounting inverter 23 on base 21a allows a reduction in space as compared with a case where inverter 23 is mounted on base 21b.

FIG. 11 is a front view of heat sink 29 and power conversion device 20 according to a second modification. In the second modification, inverter 23 is mounted on base 21b. The other conditions are the same as those in the example described with reference to FIGS. 6 to 9.

In this case, in a case where converter 24 is larger in size than chopper 25, the size (mountable area) of bases 21a and 21b may be increased so as to avoid the fins used by converter 24 and the fins used by inverter 23 from overlapping each other. Alternatively, if space saving is important, the fin used by converter 24 and the fins used by inverter 23 may overlap each other. In the latter case, mounting inverter 23 on base 21b allows a reduction in space as compared with a case where inverter 23 is mounted on base 21a.

It should be understood that the embodiment disclosed herein is illustrative in all respects and not restrictive. The scope of the present invention is defined by the claims rather than the above description, and the present invention is intended to include the claims, equivalents of the claims, and all modifications within the scope of claims.

### REFERENCE SIGNS LIST

1: uninterruptible power supply device,
10, 20: power conversion device, 11, 21: base, 12, 12a to 12c, 22, 22a, 22b: fin, 13, 23: inverter, 14, 24: converter, 15, 25: chopper, 19, 29: heat sink, 13a to 13d, 14a to 14d, 15a, 15b: power module, 30: control device, 31: commercial AC power supply, 32: load, 33: battery (power storage device), 35: bypass circuit (semiconductor switch), 36 to 38: electromagnetic contactor, T1: AC input terminal, T2: AC output terminal, T3: battery terminal.

1. An uninterruptible power supply device connected between an AC power supply and a load, the uninterruptible power supply device comprising:
a heat sink including first and second bases, and fins, the first and second bases being arranged to face each other, the fins being arranged between the first and second bases and coupled to both the first and second bases; and
a power conversion device mounted on a surface of each of the first and second bases opposite to a surface to which the fins are coupled, wherein
the power conversion device includes:
a converter to convert AC power supplied from the AC power supply into DC power, and stop when the AC power supply fails;
a chopper to regulate a voltage of DC power supplied from a power storage device while the AC power supply is in failure; and
an inverter to convert the DC power output from the converter or the DC power output from the power storage device into AC power and supply power to the load,
the inverter is mounted on either of the first and second bases,
the converter is mounted on the first base,
the chopper is mounted on the second base, and
at least some of the fins thermally connected to the converter via the first base are thermally connected to the chopper via the second base.

2. The uninterruptible power supply device according to claim 1, wherein
the fins includes first fins and second fins,
the first fins are thermally connected to the converter via the first base and are thermally connected to the chopper via the second base, and
the second fins are thermally connected to the inverter via a base on which the inverter is mounted.

3. The uninterruptible power supply device according to claim 1, wherein
the inverter is mounted on the first base.

4. The uninterruptible power supply device according to claim 1, wherein
the inverter is mounted on the second base.

5. The uninterruptible power supply device according to claim 2, wherein
the inverter is mounted on the first base.

6. The uninterruptible power supply device according to claim 2, wherein
the inverter is mounted on the second base.
